(19) United States
(12) Patent Application Publication
(10) Pub. No.: US 2025/0239488 A1
(43) Pub. Date: Jul. 24, 2025

(54) HERMETIC VIAS WITH LOWER PARASITIC CAPACITANCES

(71) Applicant: Hahn-Schickard-Gesellschaft für angewandte Forschung e. V., Villingen-Schwenningen (DE)

(72) Inventors: Alfons Dehé, Reutlingen (DE); Peter Nommensen, Villingen-Schwenningen (DE); Johannes Auber, Villingen-Schwennigen (DE)

(21) Appl. No.: 18/705,475

(22) PCT Filed: Oct. 26, 2022
(86) PCT No.: PCT/EP2022/079942

§ 371 Date: Apr. 26, 2024

(30) Foreign Application Priority Data
Oct. 27, 2021 (EP) 21204923.3

(51) Int. Cl. H01L 21/768; B81C 1/00; H01L 23/48

(52) U.S. Cl. CPC H01L 21/76898; H01L 21/76801; H01L 23/481; B81C 1/00095

(57) ABSTRACT

In a first aspect, the invention relates to a method for producing a via for a semiconductor component. The semiconductor component comprises a via region which is enclosed by vertical trenches. The vertical trenches are only partially filled with a dielectric, so that in particular the parasitic capacitances that occur have been considerably reduced.

In a second aspect, the invention relates to a semiconductor component produced by the method according to the invention.

In a first aspect, the invention relates to a method of producing a via for a semiconductor component. The semiconductor component comprises a via region which is enclosed by vertical trenches. The vertical trenches are only partially filled with a dielectric so that, in particular, the parasitic capacitances that occur are considerably reduced.

In a further aspect, the invention relates to a semiconductor component produced by the method according to the invention.

### BACKGROUND AND PRIOR ART

Vias refer to vertical electrical connections between conductive path levels, which are often found in semiconductor components. Vias are found in particular in integrated circuits. They are an integral part of modern semiconductor technology. Since wafers comprising silicon are often used in semiconductor technology, through silicon vias (TSV) are a common type of via. In particular, through silicon vias can enable vertical electrical connections between stacked microchips in 3D integrated circuits. Most importantly, MEMS devices can also be operated within the silicon wafer or within a wafer stack. Through silicon vias are therefore a proven technology for meeting the high demands on the electrical paths in respect of their short length, robustness and longevity.

Various apparatuses and methods are known in the prior art that comprise through silicon vias and use them for operation. Some of these prior art apparatuses and methods are briefly described below.

US 2005/0250238 A1 discloses a method for hermetically sealing a MEMS device on a substrate comprising silicon. For this purpose, trenches are etched down to an insulator and then filled with silicon nitride to electrically insulate an inner block of silicon from the surrounding substrate. The silicon nitride fills the trenches, covers the surface of the substrate and also insulates the top of the silicon block.

U.S. Pat. No. 8,433,084 B2 discloses a MEMS sound transducer, in particular MEMS microphones, within a wafer stack. Electrical signals caused by sound are transmitted to electrical connections through the vias, which are connected to bumps, which in turn are connected to contact pads. The vias run through a substrate, wherein the substrate comprises insulating material, for example organic material. The vias are also located outside the MEMS region.

DE 102007063742 B4 discloses a sensor that can be designed as a pressure sensor and/or acceleration sensor. A through-hole electrode, which constitutes the via, leads to a wiring conductor. The through-hole electrode is surrounded by an insulating film. The insulating film insulates the through-hole electrode from a pressure sensor substrate and/or a membrane. This insulating film is formed by thermal oxidation and completely surrounds the through-hole electrode.

A common feature of vias known in the prior art is that parasitic capacitances can occur. Parasitic capacitances can cause disadvantageous technical effects. For example, radiation or increased temperature can cause leakage currents that could damage the semiconductor component or even render it inoperable. In particular, the effects of parasitic capacitances can be seen in the form of an influence on high-frequency voltage and current oscillations after switching operations of semiconductor components. As soon as the voltage of a potential surface drops in relation to a reference potential as a result of switching on, the parasitic capacitance of the potential surface discharges. This leads to an overshoot at the end of voltage signal edges. In addition, the capacitances can couple with parasitic inductances of the structure and cause high-frequency damped oscillations.

Parasitic capacitances, also known as stray capacitances, are usually unwanted capacitances that occur between parts of electronic components or an electronic circuit, in particular due to their proximity to each other. When two electrical conductors with different voltages are close to each other, the electric field between them causes electrical charge to be stored on them. This effect is also known as parasitic capacitance. All actual circuit elements such as inductors, diodes, transistors, etc. have an internal capacitance that can cause their behavior to deviate from that of “ideal” circuit elements. The influence of stray capacitance increases with increasing frequency. In addition to the distance, the area and the frequency, the stray capacitance is particularly dependent on the permittivity

ε=ε₀εᵣ

wherein ε₀ is the electric field constant and εᵣ is the relative permittivity of a medium (designation according to standard DKE-IEV 121-12-13). The term dielectric constant can also be used synonymously with the term relative permittivity.

There are already proposals in the prior art for improving the occurrence of parasitic capacities.

US 2011/291287 A1 discloses a method for producing vias to reduce parasitic capacitance. For this purpose, it is intended to provide areas that are coated and/or filled with a dielectric material. In addition, layers of material are disclosed which can be applied around an electrically conductive section. In particular, a plurality of dielectric materials can also be used to insulate the electrically conductive sections.

DE 10 2012 219769 A1 describes a process for producing an electrical via that is characterized by high dielectric strength and voltage decoupling. For this purpose, a metal layer is first coated in a ring-shaped trench surrounding a substrate die. The introduced metal layer is converted into a metal silicide layer. The ring-shaped trench is formed beforehand using a grid region. Excess metal from the metal layer is completely removed from a lower insulation layer and the front-side electrical conductive path to ensure insulation from the surrounding substrate. The grid region is sealed with a pre-closure layer. Before this, the ring region can be completely or partially filled with an insulation layer.

DE 10 2011 085084 A1 describes a similar approach to DE 10 2012 219769 A1. According to the method disclosed in DE 10 2011 085084 A1, substrates with vias are to be produced in which undesired bending of components is avoided. By using a grid, a ring-shaped trench is first formed in the substrate. An electrically conductive layer is then applied to the ring-shaped trench to make the substrate die low-resistance. Furthermore, an insulating layer is applied to the electrically conductive layer in order to passivate the walls of the ring-shaped trench.

DE 10 2012 200840 A1 also discloses a method for manufacturing a component with a via, which can have an electronic circuit and/or a micromechanical structure. With regard to the via, a substrate area is provided by forming a trench structure. A masking layer with a grid structure is used to form the trench structure. The lateral shape of the trench structure is predetermined by the grid structure, as the trench structure is provided by an etching process through the perforations of the grid structure. The grid structure and thus also the trench structure have a circumferential closed shape in a top view. The trench structure is then coated with a diffusion barrier layer and an insulating layer, wherein only one of the two layers can be applied. The diffusion barrier layer and/or insulating layer creates an enclosed cavity within the trench structure. The use of the grid structure makes it possible to seal the trench structure, which is not only intended to be sealed via the diffusion barrier layer and/or insulating layer.

Although approaches to reducing parasitic capacitance are already known in the prior art, there is potential for improvement with regard to the reduction of parasitic capacitance in known semiconductor components with vias. In particular, there is a need for optimization in the processing of components that are characterized by a particularly low parasitic capacitance.

### Objective of the Invention

The objective of the invention is to provide an apparatus or method for the production of vias which eliminates the disadvantages of the prior art. In particular, one objective of the invention is to produce vias with minimal parasitic capacitances. In addition, the vias should be hermetically sealed. The production method should also be simple, cost-effective and suitable for mass production in order to enable applications in a wide variety of areas.

### SUMMARY OF THE INVENTION

The objective is solved by the features of the independent claims. Preferred embodiments of the invention are described in the dependent claims.

In a first aspect, the invention relates to a method of producing a via for a semiconductor component comprising at least one wafer, comprising the following steps:
a) Forming vertical trenches within the wafer that enclose a via region
b) Coating and sealing the vertical trenches with a dielectric, wherein the vertical trenches are only partially filled with the dielectric
c) Connection of the via region to an electrical connection.

The vias formed by means of the production method according to the invention have proven to be very advantageous in many aspects, which are explained below.

It is particularly advantageous that the occurring parasitic capacitances are significantly reduced. This is essentially achieved by partially, i.e. in particular not completely, filling the vertical trenches surrounding the via region with a dielectric. The parasitic capacitances can be present horizontally and/or vertically between the via region and other regions of the wafer and/or the semiconductor component.

In particular, parasitic capacitances can form between two vias that run next to each other. If current flows and/or a voltage is applied to the via region, electric and/or magnetic fields are formed between the via region and horizontal and/or vertical regions of the wafer and/or the semiconductor component. The partial filling of the vertical trenches with a dielectric weakens the electric field in particular, as the polarization in the dielectric creates an opposing electric field. Therefore, some of the field lines of the electric field end in the polarization charges on the surface of the dielectric.

Parasitic capacitances occur, for example, when two conductive paths cross at different levels and/or when two conductive paths run parallel to each other. The crossing area or the adjacent conductive paths between which parasitic capacitances occur can be modeled in a first approximation with a conventional plate capacitor. The capacitance C of a plate capacitor is calculated using

$$C = {ε}_{0} {ε}_{r} \frac{A}{d} , \qquad ( 1 )$$

wherein A is the area and d is the distance between the “capacitor plates”. It can be seen that reducing the distance d increases the capacitance C. To compensate for this, it is necessary to reduce the plate area A or the relative permittivity εᵣ. However, the conductive path cross-section and thus the plate area of the parasitic capacitances are hardly reduced. This is due to the fact that the current density in the conductive paths must not increase and smaller cross-sections increase the electrical resistance due to the stronger influence of the interfacial scattering of the electrons. It is therefore preferable to keep the relative permittivity εᵣ as low as possible. The introduction of a dielectric between two capacitor plates, on the other hand, increases the capacitance.

According to the invention, it was recognized that the capacitances that occur can be reduced by partially filling the vertical trenches surrounding the via region with a dielectric. Partial filling with the dielectric reduces its material density, in particular its dipole density, by creating free volume within the vertical trenches. The partial filling of the vertical trenches is preferably carried out by coating the side walls and the bottom of the vertical trenches with a dielectric.

The parasitic capacitances that occur in connection with the vias known in the prior art range from approximately 10⁻⁶ F (Farad) up to 10⁻¹² F. By means of the method according to the invention, vias can be formed which have parasitic capacitances of less than 10⁻¹² F, preferably less than 10⁻¹³ F, 10⁻¹⁴ F or in the range of a few 10⁻¹⁵ F or less, i.e. in the femtofarad range.

The vertical trenches that enclose the via region hermetically seal off the via region. The hermetic sealing of the via region is advantageous in that the via region and the vertical trenches themselves are protected from the surrounding atmosphere of the semiconductor component. For example, the hermetic seal ensures that a fluid cannot enter the vertical trenches and disrupt the functionality of the semiconductor component. However, care must be taken to ensure that sufficient heat dissipation is provided despite the hermetic seal so that the components do not overheat.

In particular, the partially filled vertical trenches surrounding the via region ensure that the via region is insulated. This is of particular relevance for the operational reliability of the semiconductor component. The via region should preferably conduct current between different conductive path levels. In order to avoid short circuits and/or current transport in undesired regions of the semiconductor component, for example, the via region is insulated “to the outside”. This limits the flow of electrical current only to the live parts of the semiconductor component.

For practical reasons, but also to do justice to the ever-increasing miniaturization of microsystems, the formation of vertical trenches is advantageous in that the via region has a small lateral extension. In particular, the resistance R of the via depends on various parameters, such as the specific resistance p, the length l and the cross-section A, but also on the temperature T. This can be summarized as follows

$$R = ρ \frac{l}{A} , \qquad ( 2 )$$

wherein the temperature dependence is not taken into account in this equation.

Since the specific resistance p is a temperature-dependent material constant, it is preferable to select the ratio of length l and cross-section A in such a way that the resistance R of the via region itself is kept as low as possible in order to minimize the loss of current transmission.

In addition, the vias produced using the method according to the invention have proven to be particularly advantageous in that they exert only very low mechanical stresses on the surrounding wafer material and/or other components of the semiconductor component. Such mechanical stresses can influence the functionality of adjacent components. The distribution, magnitude and direction of stresses are dependent on the production process, design and integrity of the via and the vertical trenches surrounding the via region. In particular, mechanical stresses must be considered when the via region is filled with a filler material such as copper. The vertical trenches, which are preferably partially filled with a dielectric, advantageously cushion and absorb the mechanical stresses exerted on the via region. This significantly reduces the mechanical stresses on adjacent sections of the via region.

By means of the method according to the invention, the via region can also particularly easily be electrically connected to a MEMS device and/or an electronic circuit, which are located within a cavity of a wafer or wafer stack. The via region can also extend into the cavity of the MEMS device and/or the electronic circuit.

It may also be preferable for the semiconductor component to comprise several via regions, which are correspondingly enclosed by a plurality of partially filled vertical trenches. A plurality of via regions can advantageously transport current in a plurality of different sections of the semiconductor component. The plurality of partially filled vertical trenches also advantageously result in greater flexibility of the semiconductor component, such that the semiconductor component is not spatially restricted to fixed external shapes, for example when installed in another device, and can be flexibly adapted.

For the purposes of the invention, a semiconductor component preferably refers to a component which is used for circuits in electrical engineering or electronics, in particular in connection with semiconductor materials. The average person skilled in the art knows that the term semiconductor component can be interpreted broadly. For example, a semiconductor component may comprise an integrated circuit comprising transistors and/or diodes or may itself be such a component. Preferably, the integrated circuits are produced on wafers, which may in particular comprise, but are not limited to, a semiconductor material. In addition, components such as transistors, diodes and/or capacitors can be produced using the wafer material itself by processing the wafer. A plurality of wafers can also be used, which can then be divided and form a plurality of chips. A semiconductor component can also comprise or itself be, for example, a printed circuit board, a plurality of processors, semiconductor memories, microcontrollers, converters, microchips, etc.

In particular, a semiconductor component also comprises components that occur in connection with 3D integration. 3D integration preferably refers to an integrated circuit in which the active electronic components are integrated both horizontally and vertically in two or more layers, i.e. connected to form a single circuit, a so-called three-dimensionally integrated circuit (3D IC).

A wafer can, for example, refer to a circular or square slice with a thickness in the millimeter or submillimeter range. Wafers are typically made from monocrystalline or polycrystalline (semiconductor) blanks, called ingots, and are generally used as a substrate for e.g. coatings or components, in particular MEMS components and/or electronic circuits. The use of the term substrate for the wafer is also known in the prior art, wherein the substrate preferably refers to the material to be treated. For the purposes of the invention, the terms wafer and substrate can be used synonymously.

The wafer may comprise materials selected from the group consisting of monocrystalline silicon, polysilicon, silicon dioxide, silicon carbide, silicon germanium, silicon nitride, nitride, germanium, carbon, gallium arsenide, gallium nitride, indium phosphide and/or glass.

These materials are particularly easy and cost-effective to process in semiconductor and/or microsystems technology and are also well suited for mass production. These materials are also particularly suitable for doping and/or coating in order to achieve the desired electrical, thermal and/or optical properties in specific regions. The aforementioned materials offer a variety of advantages due to the usability of standardized production techniques, which are also particularly suitable for the integration of other components, such as electronic circuits.

Vertical trenches are preferably vertical recesses in the wafer that enclose the via region. The vertical trenches are formed starting from one surface side of the wafer. Once formed, they are open to the corresponding surface side so that the vertical trenches comprise side walls and/or a bottom. They are then partially filled with a dielectric, wherein they are preferably coated with the dielectric. Coating the vertical trenches involves coating the side walls and/or the bottom of the vertical trenches with the dielectric. This can be done using certain coating processes that are known and common in microsystems technology, such as the thermal oxidation of silicon.

Preferably, the coating is applied in such a way that the side walls and the base are coated directly with the dielectric. Here, direct coating means in particular that the base and the side walls of the vertical trenches are located directly below the dielectric. According to the invention, it was recognized that sufficiently reliable electrical insulation can be achieved without the need for an intermediate layer between the dielectric and the substrate in the vertical trenches.

By partially filling the vertical trenches with the dielectric via the coating, the via region is electrically insulated. It has proven to be particularly advantageous that the coating and partial filling of the vertical trenches with a dielectric results in particularly low parasitic capacitances. In addition, the vertical trenches are preferably sealed by the dielectric so that they are hermetically sealed. Advantageously, this prevents the slightest contamination of the vertical trenches by a fluid, such as air and/or water, which could impair the function of the semiconductor component. Preferably, the vertical trenches are sealed by sealing the opening of the vertical trenches. It may be preferable for the wafer surface to be coated in a planar manner with the dielectric in order to seal the vertical trenches and thereby seal them hermetically. It may also be preferred that only the openings of the vertical trenches are sealed by the dielectric in order to hermetically seal them.

For the purposes of the invention, a via region preferably refers to a vertical electrical connection for conducting current between different conductive path levels. The diameter and, if necessary, the shape of the via region can be different, depending on the intended use. With the aid of the via region, it is advantageously possible to change the conductive path levels between two or more layers of wafers.

In the case of a silicon wafer, it is common to divide the through silicon via (TSV) into different classes. Via-first TSVs are processed before the active components (transistors etc., also known as front-end of line, FEOL). Via-middle TSVs are structured after the active components, but before they are wired (metallization, also known as back-end of line, BEOL). Via-last TSVs are finally implemented after (or during) the application of the wiring metallization, i.e. the BEOL.

The connection of the via region to an electrical connection preferably comprises the connection of the via region to a conductive path in order to establish an electrical contact to the via region.

Conductive paths (also known as conductive tracks) are electrically conductive connections with a two-dimensional course, i.e. along a plane, the so-called conductive path level or metallization layer. They are preferably used to connect electronic components on printed circuit boards and integrated circuits, i.e. they are used to supply current or voltage and/or to transmit signals. The connection between individual conductive path levels is preferably made using the via region. To prevent short circuits or high leakage currents, the conductive paths must be electrically well insulated from each other. Due to the layered structure of wiring with multiple levels, additional dielectrics can be used here. Such dielectrics are divided into two classes according to their function: a dielectric between the conductive paths in one level (inter-metal dielectric, IMD) and a dielectric between two conductive path levels (inter-layer dielectric, ILD).

In another preferred embodiment, the method is characterized in that the semiconductor component comprises a MEMS device and/or an electronic circuit which are operated by connecting the via region with an electrical connection.

For the purposes of the invention, a MEMS device preferably refers to a part or component based on MEMS technology. MEMS stands for the English term microelectromechanical system, i.e. a microsystem, whereby a compact design (in the micrometer range) is achieved with simultaneously outstanding functionality at ever lower manufacturing costs. A MEMS device can be a MEMS sensor or a MEMS actuator, for example. Many MEMS devices are known in the prior art. Advantageously, the method according to the invention can be used to operate a wide variety of MEMS devices by connecting them to the via region.

Preferred electronic circuits include, without limitation, an integrated circuit (IC), an application specific integrated circuit (ASIC), a programmable logic device (PLD), a field programmable gate array (FPGA), a microprocessor, a microcomputer, a programmable logic controller and/or any other electronic, preferably programmable, circuit.

Preferably, the MEMS device and/or the electronic circuit is present within a cavity of the wafer. It may also be preferred that, for example, two or more wafers are formed into a wafer stack comprising a cavity in which the MEMS device and/or the electronic circuit is located. The wafer stack may also comprise the aforementioned materials for the wafers.

For the purposes of the invention, a cavity preferably refers to a recess in a wafer. Advantageously, the presence of one or more cavities in a wafer or wafer stack can provide a suitable cavity for the MEMS device and/or the electronic circuit.

The connection between the via region, MEMS device and/or electronic circuit and a conductive path level allows current to be conducted between a conductive path level via the via region to the MEMS device and/or electronic circuit for operation. In particular, this can be done if the MEMS device in the cavity needs to be encapsulated and specially protected.

In a further preferred embodiment, the method is characterized in that the via region extends partially and/or continuously through the wafer. The via region can extend through the entire wafer (through hole), up to a middle layer of the wafer (blind via) and/or buried between two middle layers (buried via). Advantageously, the MEMS device and/or the electronic circuit can thus be located in different positions within the wafer or on a surface of the wafer or wafer stack and can be operated through the connection with the via region.

Every electrical component exhibits more or less strong capacitive coupling with the environment or parallel to its desired behavior. This capacitive behavior can have undesirable effects, especially at high frequencies. According to the invention, the problem is solved in particular by partially filling and coating the vertical trenches surrounding the via region with a dielectric in order to advantageously minimize the occurrence of parasitic capacitances.

In a further preferred embodiment, the method is characterized in that the wafer exhibits a front and rear side, with the via extending from the front side to the rear side, wherein a MEMS device and/or an electronic circuit are present particularly preferably on the rear side, connected to the via region. The connection enables operation of the MEMS device and/or the electronic circuit. In this preferred embodiment, the via region extends through the entire wafer (through hole).

In a further preferred embodiment, the method is characterized in that the semiconductor component exhibits a cavity in which a MEMS device and/or an electronic circuit is present, the cavity preferably being located within a wafer stack formed by at least two wafers and the via region extending through at least one of the two wafers, wherein a negative pressure, preferably a vacuum, is present within the cavity.

A wafer stack is formed from at least two wafers, but can also comprise 3, 4, 5, 6, 7, 10, 15, 20 or more wafers. The wafers can be connected to each other both horizontally and vertically in two or more layers to form a three-dimensional configuration. Vertical electrical connections between different wafers are made possible by vias. It is also preferred that further layers, such as one or more oxide layers, are present between the wafers of a wafer stack.

The use or formation of one or more SOI wafers may also be preferred. An SOI wafer is a wafer stack comprising two silicon wafers with an oxide layer between the two wafers. With the aid of SOI wafers, shorter switching times and lower power consumption, particularly with regard to leakage currents, are advantageously made possible.

The MEMS device and/or the electronic circuit can be arranged within a cavity of the wafer stack on one, two or more wafers, which are aligned and bonded for interconnection. It may also be preferable for individual wafers to be thinned, for example using known polishing processes from microsystems technology. The wafers can be thinned before or after bonding. Vertical electrical connections (vias) can also be made either before bonding or after the stack has been produced.

The bonding of wafers preferably describes a process step in semiconductor and microsystem technology in which two wafers or layers, e.g. made of silicon, quartz, glass and/or the aforementioned preferred materials, are bonded together.

Various processes can preferably be used for bonding. These are also referred to as bonding processes or bonding methods. Preferred bonding processes include direct bonding, anodic bonding, interlayer bonding, glass frit bonding, adhesive bonding and/or selective bonding.

In direct bonding, particularly of silicon wafers, hydrophilic and hydrophobic surfaces of the wafers are preferably brought into contact at high temperatures. Preferably, one wafer is pressed centrally against the other, advantageously creating a first contact point. This mechanical connection in the contact region is preferably based on hydrogen bonds and/or van der Waals interactions. The contact region thus connected is preferably extended to the remaining surface region(s) of the wafer by successively removing initially existing spacers between these surface regions. The process temperatures are preferably between 1000° C. and 1200° C. and a pressure of between 10 megapascals (MPa) and 25 MPa is exerted on the wafers. Direct bonding can preferably be used for joining two silicon wafers and/or silicon dioxide wafers.

In anodic bonding, a glass with an increased Na+ ion concentration (preferably positively charged sodium ions) is used in particular, which is preferably brought into contact with a silicon wafer. An electrical voltage is applied, which is configured in particular to generate a negative polarity on the glass. Thus, preferably and in particular with the aid of an increased process temperature, the sodium ions (Na+) diffuse to the electrode, preferably forming a space charge zone at the interface, which causes an increase in the electric field and generates Si—O—Si bonds. These bonds preferably expand successively over the entire bonding region between glass and silicon. In this way, glass and silicon wafers in particular can be bonded together. If the process is adapted accordingly, it is also possible to bond two silicon layers and/or a silicon-metal layer to a glass. The anodic bonding can preferably take place at temperatures of around 400° C., it can also preferably take place at “low temperature” at around 180° C., wherein the materials to be bonded are preferably protected. Preferably, a variety of the aforementioned materials can also be bonded.

Preferably, bonding processes with so-called intermediate layers between the wafers to be bonded can also be used, such as eutectic bonding, which is preferably based on bonding using a eutectic alloy as an intermediate layer, e.g. Si—Au (silicon-gold) or Ge—Al (germanium-aluminum). A eutectic alloy is preferably an alloy whose components are mixed in such a ratio that the entire alloy becomes liquid or solid at a certain temperature. Eutectic bonding can be used, for example, to join two silicon wafers. Preferably, however, the other aforementioned materials can also be bonded.

Glass frit bonding is also preferably based on the use of an intermediate layer between the wafers to be bonded, wherein the bond is formed in particular by melting glass solders/glass frits. Glass solder preferably comprises a glass which exhibits a low softening temperature, e.g. approx. 400° C. Glass frits preferably comprise surface-melted glass powder, the glass grains of which preferably at least partially bake or sinter together. This type of bonding can preferably combine silicon and/or silicon dioxide wafers, but preferably also other aforementioned materials.

Adhesive bonding preferably describes the formation of a bond by means of an intermediate layer comprising adhesive. Adhesive bonding can preferably be used to bond a variety of the aforementioned materials together.

Preferably, selective bonding can be carried out by photolithography, etching and/or lift-off processes.

The bonding of wafers, which have preferably been pre-processed to provide a cavity for the MEMS device and/or for the electronic circuit, makes it particularly easy to manufacture a semiconductor component.

The bonding of structures from pre-processed wafers allows the simple production of complex structures that could not be produced from a single wafer without great effort. This means that the semiconductor component can be produced without the raw material having to be laboriously machined out of the interior in order to create a cavity within the semiconductor component.

Preferably, there is a negative pressure inside the cavity in which the MEMS device and/or the electronic circuit is present. This is advantageous in that the wafers of the wafer stack are held together particularly tightly, in particular in the area of the cavity, so that the MEMS device and/or the electronic circuit are extremely well protected from the environment of the semiconductor component. It is therefore particularly preferable that there is a vacuum inside this cavity.

The average person skilled in the art knows that in reality a vacuum is never absolute, but is characterized by a considerably lower pressure compared to atmospheric pressure under normal conditions. A vacuum is a relative pressure that is below the ambient pressure.

In a further preferred embodiment, the method is characterized in that the vertical trenches are filled with a porous low-k dielectric, preferably selected from a group of porous organic materials, porous carbon-doped silicon oxide, silica gel, silicate aerogels, mesoporous silicon nitride, polysilicon and/or TEOS (tetraethyl orthosilicate), porous hydrogen silsesquioxane, mesoporous silicate glasses, phosphorus particles and/or aluminum oxide particles.

In semiconductor technology, a low-k dielectric is a material that has a substantially lower relative permittivity than silicon dioxide (SiO₂), i.e. εᵣ<3.9.

The use of low-k dielectrics has proven to be particularly advantageous, as this significantly reduces parasitic capacitances.

Terms such as substantially, around, about, approx. etc. preferably describe a tolerance range of less than ±40%, preferably less than ±20%, particularly preferably less than ±10%, even more preferably less than ±5% and in particular less than ±1% and always include the exact value. Similar preferably describes quantities that are approximately equal. Partial preferably describes at least 5%, particularly preferably at least 10%, and in particular at least 20%, in some cases at least 40%.

The structures are miniaturized in order to improve the properties of semiconductor components that comprise MEMS devices and/or electronic circuits, such as integrated circuits, to reduce the power consumption of highly integrated circuits or to achieve higher switching speeds. Due to the ever-increasing miniaturization of microelectronic components, physical effects that can disrupt the functional operation of semiconductor components in this size range are becoming increasingly important. One effect of miniaturization is the reduction in the distance between the conductive path levels for establishing contacts. This reduction in the insulator thickness between two conductive paths increases the influence of parasitic capacitances. They disrupt the function of circuits, for example, and reduce the maximum switching speed.

As explained at the beginning, relative permittivity is a relevant variable when considering parasitic capacitances. Equation (1) makes it clear that reducing the distance d increases the capacitance C. To compensate for this, it is necessary to reduce the “plate area” A, which substantially corresponds to the conductive path cross-section, or the relative permittivity εᵣ. However, the conductive path cross-section and thus the plate area of the parasitic capacitances are hardly reduced, as the current, in particular the current density, must not increase in the conductive paths and smaller cross-sections increase the electrical resistance due to the stronger influence of electron scattering on the interface. Low-k dielectrics represent a new development for insulating layers with low relative permittivity.

One way of reducing the relative permittivity or keeping it as low as possible is to reduce the polarizability by using materials with few polar bonds. Well-known examples of such bonds are carbon-carbon (C—C), carbon-hydrogen (C—H), silicon-fluorine (Si—F) and/or silicon-carbon (Si—C) bonds. The above-mentioned materials exhibit these bonds, among others, such that the relative permittivity is advantageously reduced in order to keep the value of the parasitic capacitances as low as possible.

Another way to reduce the relative permittivity and thus the parasitic capacitances is to reduce the material density, or in particular the dipole density, by forming free volume. According to the invention, this is achieved by partially filling the vertical trenches and merely coating them with a dielectric, preferably a low-k dielectric. Preferably, the vertical trenches are not completely filled. Another way of creating free volume to reduce the dipole density is to use porous dielectrics, in particular porous low-k dielectrics, to partially fill the vertical trenches. In this case, partial filling can also involve almost complete filling with porous low-k dielectrics, wherein a free volume (not completely filled with a material) remains due to the pores present.

In preferred embodiments of the invention, the vertical trenches can also be coated and sealed with a dielectric, wherein the vertical trenches are only partially filled with the dielectric, by filling using a porous low-k dielectric, wherein the partial filling is provided by the remaining cavities in the porous dielectric.

The additional free volume, which is formed by the fact that vertical trenches are coated and, in particular, an empty space remains free, in combination with the porous structure of the low-k dielectric, results in a particularly reduced relative permittivity, such that parasitic capacitances are advantageously reduced considerably. Porous here preferably means that the material is permeable and/or in particular has pores, i.e. fine holes. Different pore sizes can preferably be used, for example micropores (pore size smaller than 2 nm), mesopores (pore size between 2 and 50 nm) and/or macropores (pore size larger than 50 nm).

In a further preferred embodiment, the method is characterized in that a negative pressure, preferably a vacuum, is present within the vertical trenches after sealing.

A negative pressure within the vertical trenches leads to a particularly tight and hermetic seal, which facilitates a high degree of reliability and optimum functionality. In the case of a vacuum, a relative permittivity or dielectric constant of approx. 1 is achieved.

In a further preferred embodiment, the method is characterized in that prior to sealing, the vertical trenches are filled with a gas which preferably has a lower dielectric constant than the dielectric for sealing.

Advantageously, the additional dielectric gas further significantly reduces the relative permittivity and thus also any parasitic capacitances that occur. Preferably, the dielectric gas is non-flammable in order to reduce potential hazards while it is being introduced into the vertical trenches. It is also preferred that the gas is chemically inert to the wafer material and/or dielectric used to coat the vertical trenches, in order to avoid possible damage. In particular, environmentally friendly and/or non-toxic dielectric gases are preferred.

A dielectric gas can also be referred to as an insulating gas. A dielectric gas is preferably a dielectric material in the gaseous state that can prevent an electrical discharge and/or serve as insulation. Air, sulphur hexafluoride (SF₆), ammonia (NH₃), carbon dioxide, carbon monoxide, nitrogen and hydrogen are examples of gaseous dielectric materials.

The relative permittivity or dielectric constant can be adjusted by the gases. Ammonia has a dielectric constant of 1.0007 at a pressure of 1 bar, while this is 1.00059 for air. In contrast, dielectric materials for coating the trenches, such as silicon dioxide, exhibit a dielectric constant of approx. 3.9, or silicon nitride a dielectric constant of approx. 7. Therefore, a further reduction in parasitic capacitance can be achieved by introducing the dielectric gases into the only partially filled trenches.

It has been found to be preferable that the vertical trenches substantially exhibit an aspect ratio of up to 50:1 and/or substantially a depth of between 100 μm and 1000 μm. In particular, the aspect ratio of height to width can range from 15:1 to 50:1. In further embodiments, the depth can range from 1 μm to one or more millimeters. One example is an aspect ratio of approx. 30:1 with a depth of between 10 μm and 200 μm. The aforementioned aspect ratios have proven to be advantageous in that the mechanical stresses within the wafer, the wafer stack and/or the semiconductor component itself lead to a distortion close to zero.

The aspect ratios mentioned are also relevant in that an interior of the vertical trenches, i.e. in particular the side walls and the base, can be coated with a dielectric and thus partially filled particularly easily using reliable coating processes known in the prior art. Particularly with regard to the lateral extension of the opening of the vertical trenches, the aspect ratios mentioned are advantageous in that they can be sealed very easily and particularly well by conformal deposition of a dielectric. This hermetically seals the vertical trenches, preventing an exchange of substances with the environment of the wafer, the wafer stack and/or the semiconductor component.

The aspect ratio is the ratio of the depth or height to its (smallest) lateral extension. If, for example, a 40 μm wide, arbitrarily long and 100 μm deep trench is created in a silicon wafer using an etching process, this trench has an aspect ratio of 2.5:1. Such aspect ratios greater than 1 require the use of anisotropic structuring methods, such as reactive ion etching (RIE). In the case of monocrystalline wafers, such as silicon wafers, structures with a high aspect ratio can also be produced wet-chemically by anisotropic etching, for example with potassium hydroxide solution.

In a further preferred embodiment, the method is characterized in that the vertical trenches exhibit an opening and, starting from a width of the opening, are widened laterally to form a widened region.

The opening preferably refers to a first section of the vertical trenches, which is formed starting from a surface side. The widened region preferably refers to a deeper second section, which is widened laterally in relation to the opening.

The lateral widening into a widened region increases in particular the width of the vertical trenches and thus also the distance of the via region from other regions of the wafer and/or the semiconductor component, for example from other via regions. According to equation (1), this also means that the parasitic capacitances are advantageously further reduced by the lateral widening to form a widened region. In addition, the lateral widening to form the widened region means that the lateral dimension of the via region itself is kept small, which is advantageous in order to ensure the smallest possible dimension of the semiconductor component and also the lowest possible internal resistance of the via region.

It is preferred that the vertical trenches in the region of the widened region are additionally widened laterally by at least 2 μm, preferably by at least 5 μm or also by at least 10 μm compared to the width of an opening, wherein it is preferred that the lateral widening is less than 20 μm, preferably less than 10 μm.

Furthermore, it is preferred that the opening has a depth of less than 5 μm and a width of less than 2 μm and/or the widened region has a width of at least 10 μm, preferably at least 20 μm. In preferred embodiments, the opening has a depth of at least 0.5 μm, preferably at least 1 μm, and a width of at least 0.1 μm, preferably at least 0.5 μm. The lower the depth of the opening, the wider the widened region of the vertical trench can be widened and thus the parasitic capacitance can be further reduced. The width of the opening can also be a process-relevant variable, as it is particularly easy to seal the opening with a dielectric if it is as narrow as possible. In particular, if the width of the opening is small, it is advantageously sufficient to deposit the thinnest possible dielectric layer in order to seal the vertical trench.

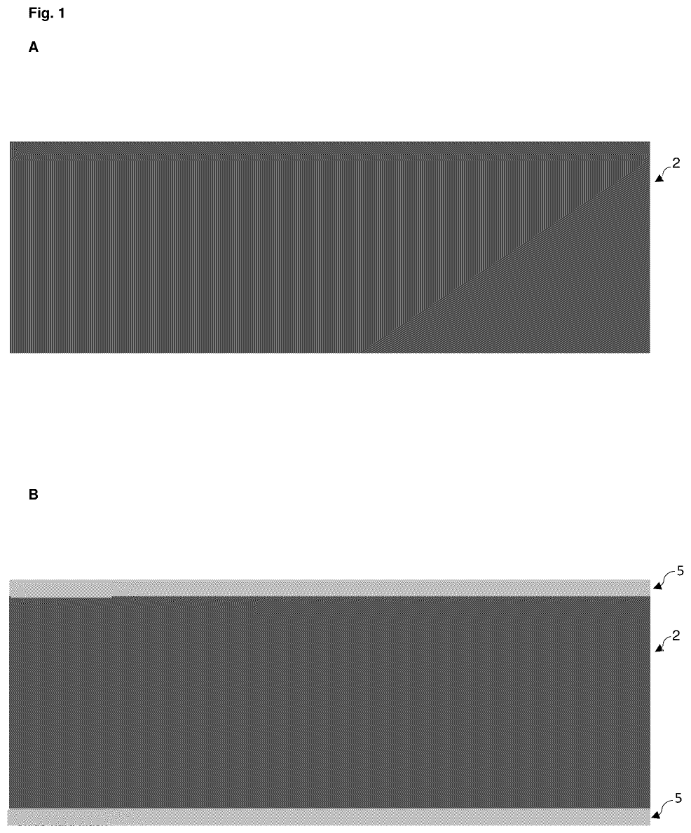

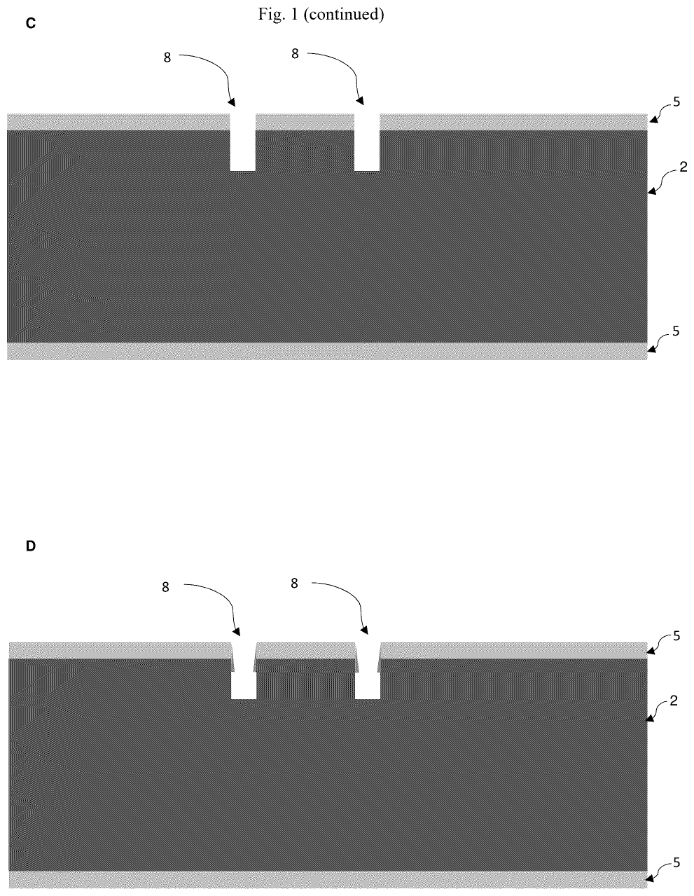

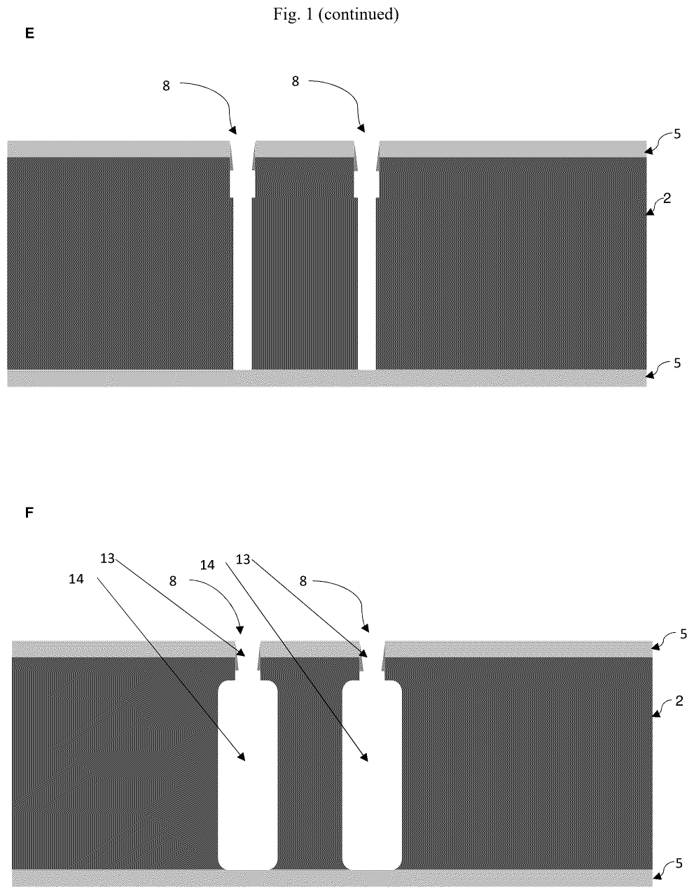

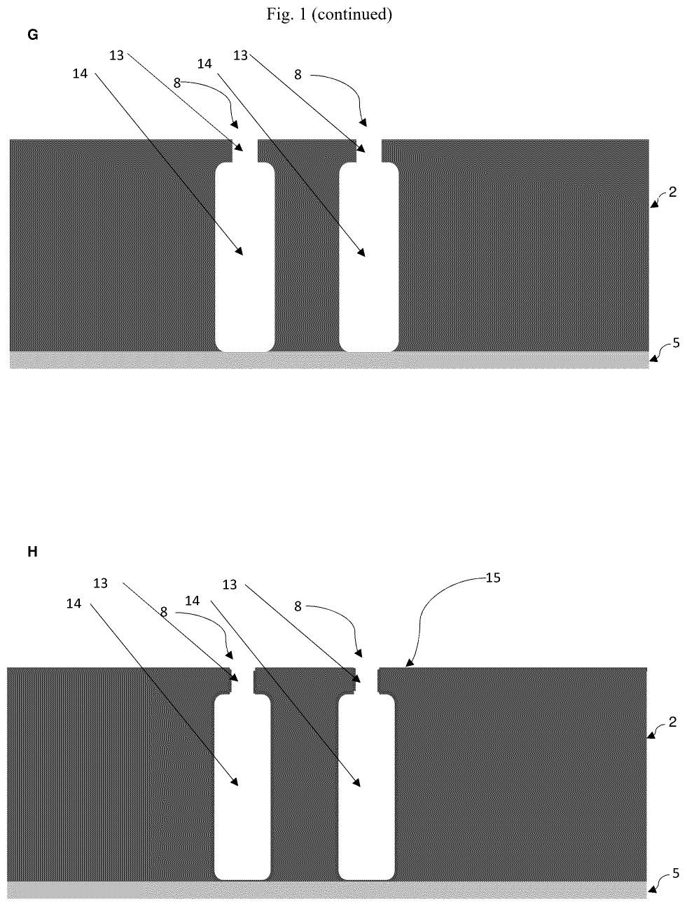

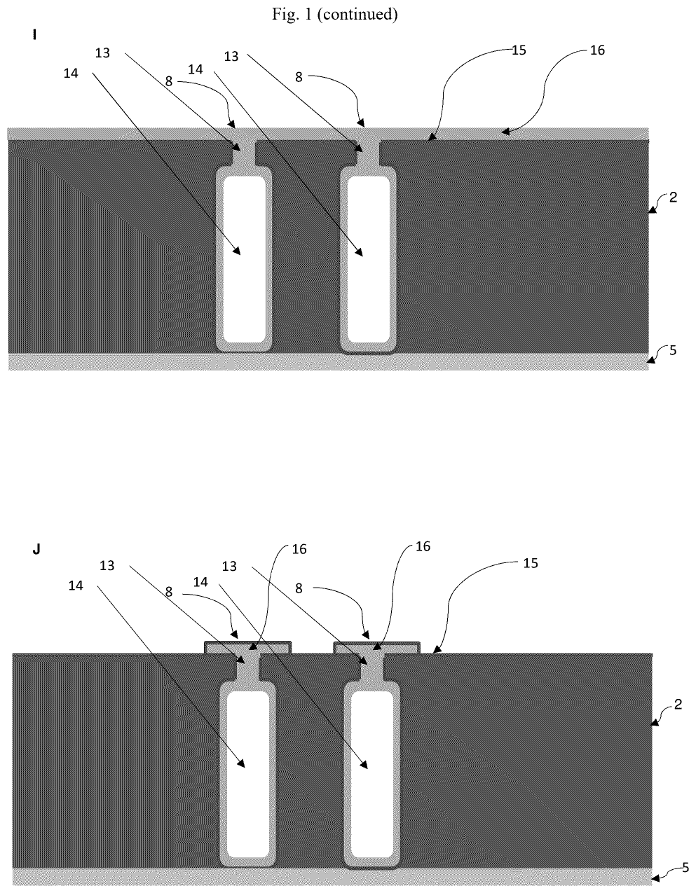

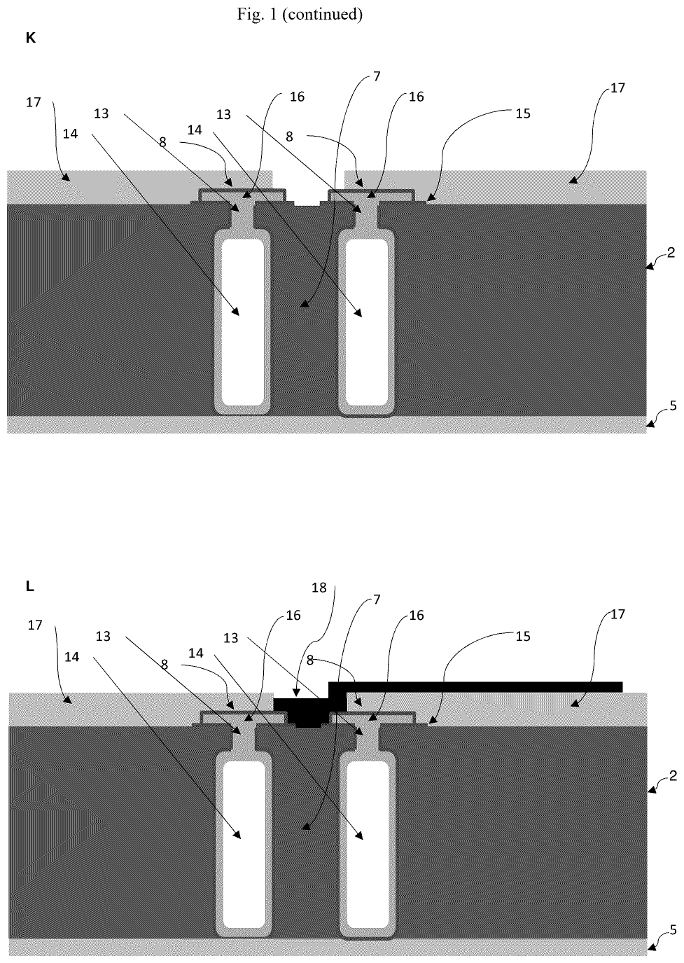

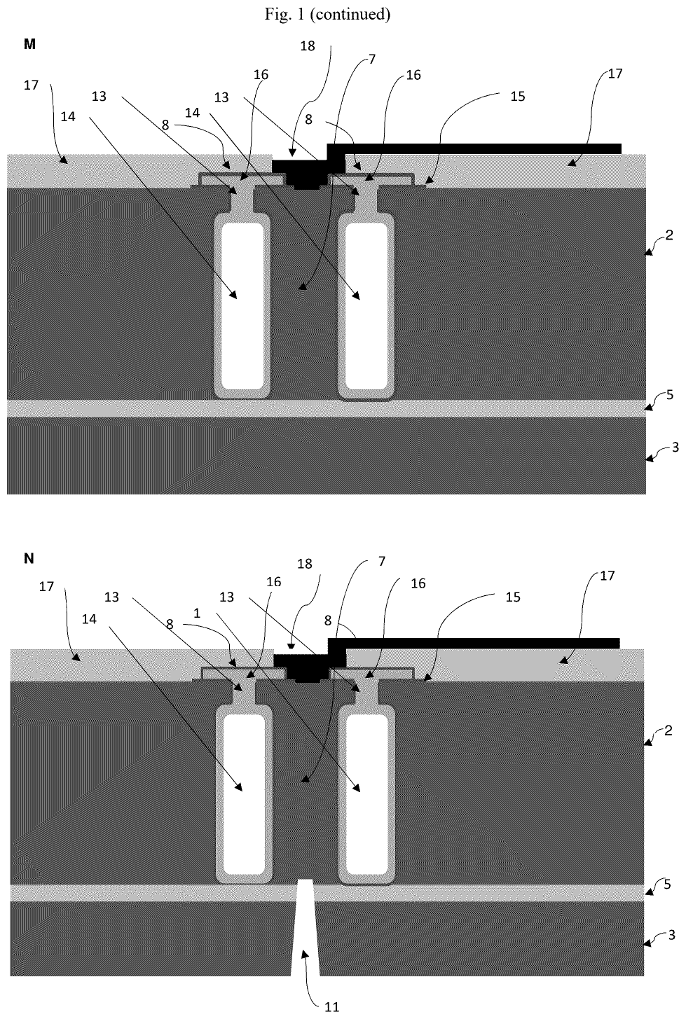

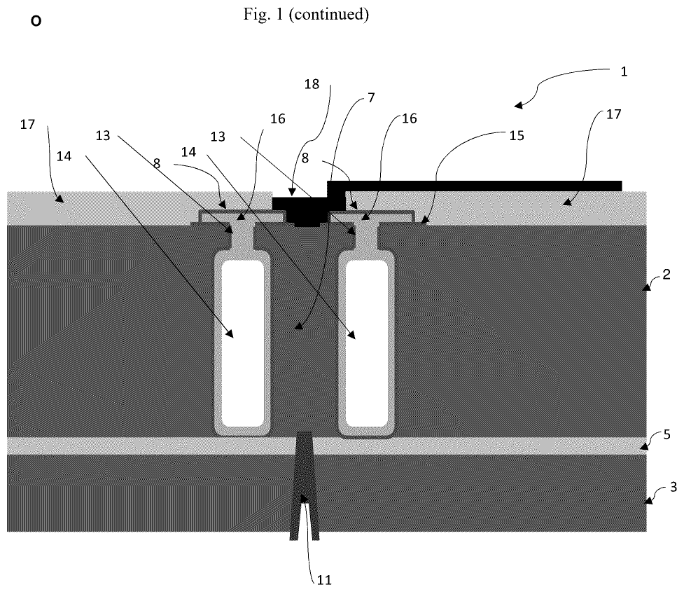

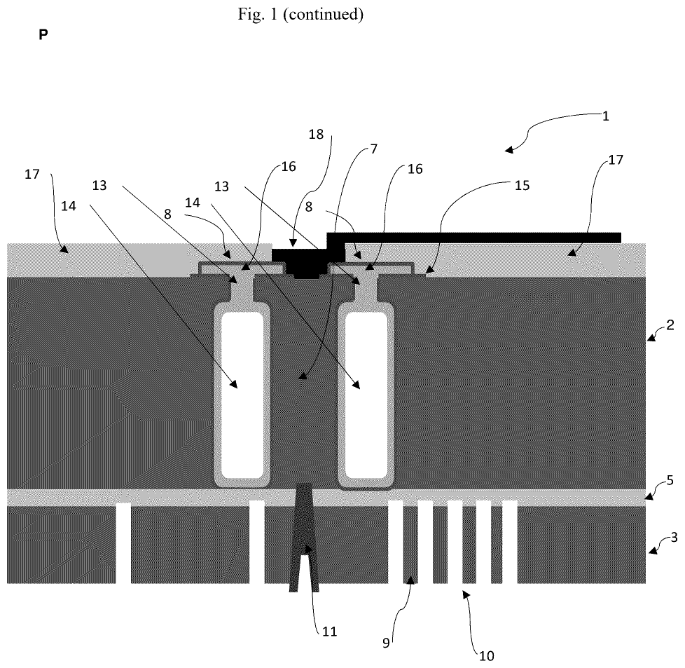

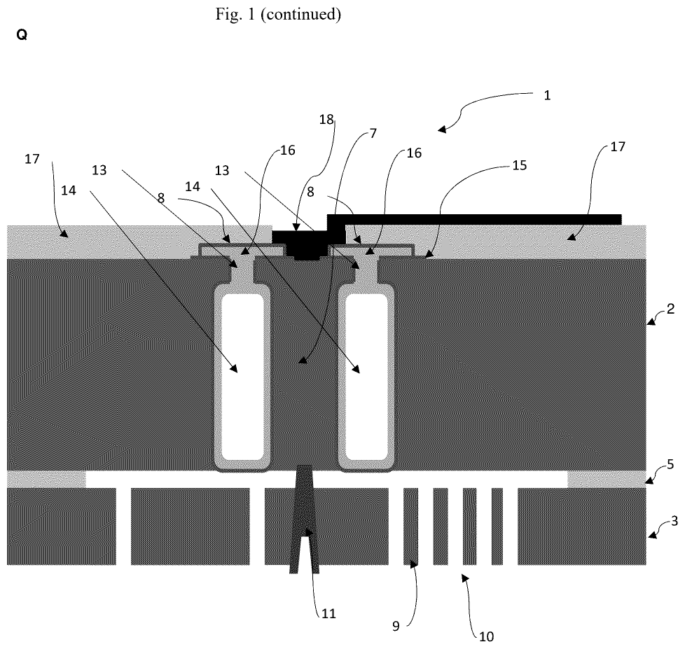

Preferably, the vertical trenches have an opening and a widened region, which are present as structures in the substrate. The opening is characterized by shortened lateral dimensions compared to the widened region. For example, it may be preferable for the opening to have a width of between 0.5 μm and 2 μm, while the widened region has a width of at least 10 μm, preferably at least 20 μm. In other words, the widened region preferably refers to a section of the vertical trenches that has larger lateral dimensions than the opening. In a cross-sectional view, the vertical trenches therefore preferably have a tapered section in the sense of an opening, which is converted into a widened trench section in the sense of a widened region. For this purpose, it may be preferable to first widen a vertical trench with a small width of, for example, less than 2 μm laterally by means of an etching process to form a widened region (see FIG. 1F). This results in a vertical trench with a narrow tapered area or opening with a width of less than 2 μm and a depth of, for example, between 1 μm and 5 μm and an underlying widened region with a width of at least 10 μm, preferably at least 20 μm and a depth of at least 100 μm, preferably 200 μm or more. As explained in detail herein, the laterally widened section or widened region advantageously leads to a reduction in parasitic capacitance, while the narrow tapered section or opening ensures a particularly hermetic seal after corresponding coating and sealing.

In a further preferred embodiment, the process is characterized in that the vertical trenches, in particular the opening and/or the widened region, are formed by wet chemical etching processes and/or dry etching processes, preferably physical and/or chemical dry etching processes, particularly preferably by reactive ion etching and/or reactive ion deep etching (Bosch process), or by a combination of the aforementioned etching processes.

An etching process preferably refers to the removal of material from a surface. The term etching method can also be used synonymously. The removal can take the form of recesses that leave cavities on wafers.

In semiconductor technology and microsystems technology, dry etching refers to a group of ablative microstructure processes that are not based on wet-chemical reactions (such as wet-chemical etching, chemical-mechanical polishing). The material is removed either by accelerated particles or with the aid of plasma-activated gases. Chemical and physical effects are utilized, depending on the process.

Dry etching processes can be divided into three groups. Firstly, physical dry etching processes, which are based on material removal by bombardment with particles, and secondly, chemical dry etching processes, which are based on a chemical reaction of a mostly plasma-activated gas.

The third group, the physical-chemical dry etching processes, combines processes that use both mechanisms of action and is thus able to minimize the disadvantages of the first two groups.

In wet chemical etching, an etch-resistant mask is transferred to the wafer by a chemical removal process.

Plasma etching is a material-removing, plasma-assisted dry etching process. In plasma etching, a distinction is made between etching removal due to a chemical reaction and physical removal of the surface due to ion bombardment.

In chemical plasma etching, the material is removed by a chemical reaction. It is therefore generally isotropic and, due to its chemical nature, also very material-selective. Physical plasma etching, also known as plasma-assisted ion etching, is a physical process. This process can result in a certain preferred direction in the etching attack, which is why the processes may exhibit anisotropy in the material removal. In physical plasma etching, non-reactive ions are generated in the plasma. These ions are accelerated onto a surface by an applied electric field and thus remove parts of the surface. This process is typically used to remove the natural oxide on silicon wafers.

Reactive ion etching (RIE) is an ion-assisted reactive process. Since the etching behavior can be easily controlled, RIE is a process for the production of topographic structures for microsystem and nanosystem technology. The process allows both isotropic (direction-independent) and anisotropic etching through chemical-physical ablation. Etching is carried out using charged particles (ions) generated in a gas plasma. A corresponding masking (e.g. produced by photolithography) of the surface gives the structures their shape.

Deep reactive ion etching (DRIE) is a further development of reactive ion etching (RIE) and a highly anisotropic dry etching process for the production of microstructures in wafers with an aspect ratio of up to 50:1, wherein structure depths of several 100 micrometers can be achieved. The DRIE process is a two-stage, alternating dry etching process in which etching and passivation steps alternate. The aim is to etch as anisotropically as possible, i.e. directionally perpendicular to the wafer surface. In this way, for example, very narrow trenches can be etched.

The aforementioned etching processes are known to the person skilled in the art. Depending on the desired openings in the wafers provided, advantageous processes can be selected to ensure efficient implementation.

In a further preferred embodiment, the method is characterized in that the vertical trenches are sealed with a dielectric.

In particular, it was recognized in accordance with the invention that the dielectric can be used both for electrical insulation and for hermetically enclosing or sealing the vertical trenches. Furthermore, it was found that no additional structure, such as a grid structure, is required to ensure secure hermetic sealing of the vertical trenches. Instead, for example, electrical insulation and hermetic sealing can be achieved within a coating process. Advantageously, this leads to improved processability and efficiency, because an additional method step, namely the provision of a grid or grid structure, can be dispensed with. For this purpose, a structure of vertical trenches comprising an opening and a widened region with the aforementioned preferred dimensions has proven to be particularly advantageous. In particular, the coating of a tapered area of the vertical trenches in the sense of an opening with a depth of between 0.5 μm and 5 μm and a width of less than 2 μm already provides good results in terms of a hermetic seal.

The hermetic seal achieved can effectively prevent the entry of foreign substances, such as liquids and/or vapors. In particular, this also prevents temperature fluctuations from causing bursting and thus a loss of function after the ingress of liquids or vapors. Advantageously, a particularly robust and durable semiconductor component can thus be provided.

Preferably, the vertical trenches can be sealed in a planar manner with the dielectric. Sealing the vertical trenches with a dielectric has proven to be advantageous in various respects. On the one hand, the vertical trenches achieve a particularly good hermetic seal when sealed with a dielectric, and on the other hand—especially in the case of a planar seal—it is particularly easy to carry out further planar processes of the method during production. Such a planar process can, in particular, be the planarization of wafers. For example, conductive paths create a certain structural pattern on the surface of the wafer resulting in a disruptive unevenness (e.g. disturbance of the lithography due to oblique reflection, irregularities in subsequent depositions). For this reason, the wafer is planarized again, in particular at multiple points in the production process. This can be done, for example, by selective etching or chemical mechanical polishing (CMP). Polishing is not the only process that leaves particles on the surface, which must be completely clean and flat for the next lithography step. Etching processes, for example, also leave behind residues of undesirable reaction products. In the first case, the wafers are cleaned mechanically using brushes and an ultrasonic bath, in the second case using wet chemical processes and also ultrasound. In order to carry out additional planar processes on the wafer and/or on the wafer stack particularly easily, it has proven to be advantageous that the vertical trenches are sealed in a planar manner with a dielectric.

Planar sealing of the vertical trenches refers in particular to a coating of the wafer with a dielectric, wherein the dielectric extends substantially along the plane of the wafer in which the vertical trenches are formed.

In a further embodiment, the method is characterized in that the vertical trenches are hermetically sealed by coating them with the dielectric and/or a sealing layer is additionally applied for hermetic sealing, wherein the dielectric for partially filling and coating the vertical trenches and/or the sealing layer comprises silicon nitride, tetraethyl orthosilicate (TEOS), silicon oxynitride and/or silicon dioxide.

These materials are particularly easy and inexpensive to process and are ideal for mass production. These materials are also particularly suitable for processing and/or coating in order to form an optimum hermetic seal on the vertical trenches. According to the invention, for a particularly good hermetic seal, a sealing layer is preferably applied, with which the vertical trenches are partially filled and/or which is applied to the side walls and the base in addition to the dielectric. The aforementioned materials offer great advantages, which are very well suited for coating and lining the vertical trenches due to the use of standardized production techniques.

The partial filling and coating of the vertical trenches is preferably carried out using coating processes known in the prior art. Preferably, the coating is carried out by a coating process within the coating system, preferably by spray coating, mist coating and/or steam coating.

A spray coating refers in particular to the application of a dielectric over a large area, wherein the dielectric is preferably pressurized before spraying (e.g. to a pressure greater than the prevailing ambient pressure) so that fine particles/aerosols of the dielectric and/or a foam are created. This allows a particularly fine coating to be achieved that covers all sprayed areas, even if these exhibit surfaces that are at an unfavorable angle to the direction of spraying, for example. Even surfaces/areas that are angled towards each other can preferably be covered directly in this way.

Preferably, a liquid dielectric is atomized under increased pressure compared to the environment and applied over a large area.

The spray coating is preferably a spray lacquering. The spray coating can also be a vapor phase deposition.

A mist coating preferably comprises a coating by fine droplets of the dielectric, which are finely dispersed in an atmosphere (preferably a gas). A vapor coating is preferably carried out by applying a dielectric in vapor form or in gaseous form.

Preferably, the coating is applied using a coating system, which can be a physical coating system or chemical coating system, preferably a plasma-supported chemical coating system, low-pressure chemical and/or epitaxial coating system.

A physical coating system preferably refers to a coating system that applies the coating by physical vapor deposition. Physical vapor deposition (PVD), rarely also physical steam deposition, refers to a group of vacuum-based coating processes or thin-film technologies. Unlike chemical vapor deposition processes, physical processes are used to transform the starting material into the gas phase. The gaseous material is then applied to the wafer to be coated, where it condenses and forms the target layer.

An epitaxy coating system preferably refers to a system in which an epitaxy process is used, preferably molecular beam epitaxy. Molecular beam epitaxy (MBE) is a physical vapor deposition (PVD) process used to produce crystalline thin layers (or layer systems). Epitaxy means that the crystal structure of the growing layer adapts to that of the substrate as long as the physical properties of the two substances do not differ too greatly.

Sputtering, also known as cathode sputtering, is a physical process in which atoms are released from a solid (target) by bombardment with high-energy ions (mainly noble gas ions) and pass into the gas phase.

In sputtering, materials such as silicon dioxide, silane, aluminum nitride, aluminum dioxide and/or mixtures of these materials (without being limited to this) can be used as a dielectric for partial filling. Sputtering is preferably carried out below approx. 200° C. for the context according to the invention. For example, carrier gases (e.g. nitrogen) or noble gases (e.g. argon) can be used as residual gases. A preferred residual gas pressure is less than approx. 500 mbar or less than approx. 100 mbar.

In preferred embodiments, metal can also be introduced into the vertical trenches during sputtering, wherein it is important that a continuous layer is not formed within the vertical trenches in order to avoid an electrical short circuit. The hermetic seal can be rated as very good, particularly with the above preferred process parameters.

Coating by means of electroplating (also known as electroforming or galvanization) may also be preferred. Electroplating preferably refers to the electrochemical deposition of material deposits, i.e. coatings on wafers in an electrolytic bath.

A chemical coating system preferably refers to a coating system that uses chemical vapor deposition to apply coatings. In chemical vapor deposition (CVD), a solid component is deposited from the gas phase on the heated surface of a wafer as a result of a chemical reaction. One particular feature of the process is the conformal layer deposition, wherein even the finest recesses in wafers, for example, are coated evenly. Chemical vapor deposition also comprises atomic layer deposition (ALD).

Plasma-enhanced chemical vapor deposition (PECVD), also known as plasma-assisted chemical vapor deposition (PACVD), is the preferred term for a system that uses the plasma-enhanced or plasma-assisted chemical vapor deposition process. The plasma can burn directly on the wafer to be coated (direct plasma method) or in a separate chamber (remote plasma method). While in CVD the dissociation of the molecules of the gas is achieved by the external supply of heat and the energy released by the subsequent chemical reactions, in PECVD this task is performed by accelerated electrons in the plasma. In addition to the radicals formed in this way, ions are also generated in a plasma, which together with the radicals cause the layer deposition on the wafer. The gas temperature in the plasma generally increases by a few hundred degrees Celsius, which means that, in contrast to CVD, more temperature-sensitive materials can also be coated. In the direct plasma method, a strong electric field is applied between the wafer to be coated and a counter electrode, which ignites a plasma. In the remote plasma method, the plasma is arranged in such a way that it has no direct contact with the substrate. This provides advantages in terms of selective excitation of individual components of a process gas mixture and reduces the possibility of plasma damage to the wafer surface by the ions.

In the context of coating using PECVD, it may be preferable to use silicon dioxide for partial filling in the vertical trenches. Residual gases can be, for example, dinitrogen monoxide, silane and/or hydrogen, wherein a residual gas pressure can be between approx. 10⁻³-10⁻² mbar, for example, depending on the deposition temperature. A process pressure can preferably be less than 10 mbar or less than 1 mbar, depending on the reaction in the cavity.

Furthermore, silicon nitride can be used in a PEVCD coating to partially fill and hermetically seal the vertical trenches. Residual gases, such as ammonia, silane and/or hydrogen, can be used during the preferred production process, for example to enable rapid bonding to the substrate and/or to regulate the pressure conditions. At a deposition temperature of approx. 300° C. and a residual gas pressure of approx. 10⁻³-10⁻² mbar, a process gas pressure of less than 10 mbar, in particular also less than 1 mbar, can be achieved in the vertical trenches.

Furthermore, silicon oxynitrides with corresponding residual gas mixtures can also be used for a coating process using PECVD.

The aforementioned materials and process parameters have proven to be particularly suitable for ensuring a good hermetic seal. The process parameters can also be optimized. For example, an increased deposition temperature facilitates a low internal residual gas pressure.

Low pressure chemical vapor deposition (LPCVD) is the process frequently used in semiconductor technology for the deposition of silicon oxide, silicon nitride and polysilicon, as well as metals.

Other methods can also be used to seal the vertical trenches.

In a preferred embodiment, the opening can be sealed by means of a covering process.

Preferably, a film or photoresist (e.g. SU-8) can be used for this purpose, which makes processing particularly easy. The pressure inside the cavities would then substantially correspond to the ambient pressure.

It may also be preferable to use a spin coating or spin-in. For example, a (liquid) imide can be used, which is drawn into the opening due to the narrow lateral dimensions and capillarity. Due to the existing pressure within the vertical trenches, the vertical trenches are advantageously not completely filled. Advantageously, the process parameters during a spin coating can be used to control the placement of the imide particularly easily, reliably, and precisely, in particular to prevent the formation of bubbles.

Glass, for example, can also be used to seal the vertical trenches. For example, a glass (e.g. borophosphosilicate glass) can be coated (e.g. with a thickness of approx. 1-2 μm). Once the vertical trenches have been formed, they can be sealed in an oven by means of a flow process at approx. 900° C. and above. Advantageously, low negative pressures, such as less than 10 mbar, can also be achieved.

In a further preferred embodiment, the method is characterized in that, in order to provide an electrical connection, a region on the via region is connected to a conductive material, wherein preferably a region of an oxide layer on the via region is structured and/or omitted and the conductive material is connected to the via region in the region of an omission.

Advantageously, direct electrical contact with the via region can be made possible. The conductive material can, for example, be provided by one or more metal layers to provide the current transmission.

In a further embodiment, the method is characterized in that a connection opening is formed, which is filled with a conductive material, for connecting an electrical connection for operating the MEMS device and/or the electronic circuit to the via region. The connection opening can be formed in one or more wafers of a wafer stack. Thus, the connection opening can be provided in embodiments that cover only one wafer as well as in embodiments in which a wafer stack is preferred.

The connection opening provides a (preferably internal) electrical connection to the via region, which allows the MEMS device or the electronic circuit to make contact with the via region. The connection opening can be formed in a wafer and/or a wafer stack. The etching processes mentioned above are preferred for this purpose. A cavity is formed by the etching process, which preferably extends to the via region. Furthermore, it may be preferred that the connection opening extends into the via region.

Since the via region is a vertical section for conducting electrical current between different conductive path levels, the via region preferably has two connection areas which for operation must be electrically connected and sealed, in order to form an electrical circuit. Preferably, a first (internal) connection region is formed by a connection opening or by filling the connection opening with an electrically conductive material and a second (external) connection region is formed by a connection pad for external connection to the semiconductor component. Both connection regions are preferably part of the electrical connection for operating the MEMS device and/or the electronic circuit.

In a further embodiment, the method is characterized in that the conductive material for the connection opening is a metal or a semiconductor material, preferably monosilicon or polysilicon.

By filling the connection opening with a conductive material, an electrical connection can be established between the connection opening and the via region. Metals and/or semiconductor materials are suitable for creating an electrical connection. They are inexpensive and simple to manufacture and have a high degree of efficiency.

In a further embodiment, the method is characterized in that a connection pad is attached on a contact side of the wafer or wafer stack on the via region, whereby for this purpose an insulating layer is preferably first applied to the wafer or wafer stack, leaving out at least part of the via region, and the connection pad is formed by filling the omitted area with a conductive material.

By forming the connection pad, a second (external) connection region is provided for the electrical connection of the via region in order to form a closed circuit for the operation of the MEMS device and/or the electronic circuit. Preferably, the connection pad is formed by first applying an insulating layer to a contact side of the wafer. The insulating layer is preferably coated in such a way that the spatially lateral region of the via region is not coated.

It may also be preferable to substantially completely coat the contact side of the wafer and/or the wafer stack with the insulating layer and then structure it in the area of the via region. The structuring is intended to remove the insulating layer in the area of the via region. This creates an opportunity to establish electrical contact with a connection region of the via region. Structures formed in this way can include corners, edges, recesses, depressions and/or holes. The insulating layer or the structuring of the insulating layer on the via region enables targeted electrical contact to be made with it. In particular, the insulating layer prevents electrical contact between the connection pad and other regions of the wafer and/or wafer stack, so that short circuits are avoided.

A connection pad is formed by filling the omitted area of the via region with an electrically conductive material so that the via region can also be electrically connected to the second connection region. The connection pad is preferably used to establish an electrical connection with the via region. This makes it possible to close a circuit in order to operate the MEMS device and/or the electronic circuit.

In a further preferred embodiment, the process is characterized in that the via region between the vertical trenches is removed and filled with a metal, preferably copper, aluminum, iron, zinc, tin, tungsten, gold, their compounds and/or alloys.

Preferably, the removal of the wafer material in the via region is carried out by one of the etching processes described above and the filling of the via region with the aforementioned materials is carried out by the coating processes described, wherein sputtering and/or electrodeposition are particularly preferred here.

The aforementioned materials have proven to be very good and reliable electrical conductor materials in the prior art and can be easily and quickly introduced into the vertical trenches using the known coating methods. In particular, the aforementioned materials exhibit a low specific resistance, such that the current is conducted particularly well.

In a further preferred embodiment, the method is characterized in that a sensor structure for the MEMS device is introduced into the wafer or into the wafer stack, preferably using a hydrogen fluoride underetching process (also HF underetching process, HF undercutting or simply just vapor underetching, HF stands for hydrogen fluorine) to form the sensor structure.

HF underetching advantageously allows sensor structures to be exposed without the possibility of the wafer sticking together and without (time-consuming) complex etching processes such as DRIE.

Various approaches and systems are known in the prior art with which HF underetching can be implemented. For example, it may be preferable to use methods for HF underetching described in Zhang et al. (2014).

Preferably, an oxide layer and/or other layers of the wafer and/or the wafer stack and/or the semiconductor component are removed by the HF underetching in order to obtain preferably freely vibratable sensor structures for the MEMS device and/or for the electronic circuit.

Sensor structures preferably refer to components and/or sections of a wafer or a wafer stack that are configured for the MEMS device. They can preferably process mechanical and/or electrical information and be suitable for sensors and actuators, but also oscillators and filters. The sensor structures can have characteristic dimensions in the micrometer range, but also beyond. The possibilities known in the prior art allow sensor structures to be produced simply, cost-effectively and on a mass scale.

In a further preferred embodiment, the method is characterized in that the semiconductor component comprises a MEMS device and/or an electronic circuit, wherein the MEMS device comprises an acceleration sensor, a gyroscope, a pressure sensor, a microphone, a flow sensor and/or a gas sensor and/or the electronic circuit, a radio frequency device, an integrated readout circuit and/or an amplifier.

Compared to conventional macroscopic systems, MEMS devices primarily offer advantages in terms of cost savings, for example through significantly lower consumption of materials and/or the parallel production of a plurality of MEMS devices, and in terms of efficiency, for example through lower energy and power requirements. They also offer a wide range of functions, high functional densities and new functionalities. Integration and miniaturization entail short information paths and short response times. They are also more reliable than conventional systems, mainly due to the elimination of plugs and cables or error-prone precision mechanical elements.

A MEMS device preferably comprises a miniaturized device, an assembly and/or a part whose components have very small dimensions in the μm range and interact as a system. The use of MEMS devices is conceivable wherever sensors/actuators and electronics work together and are expedient for the application.

An acceleration sensor usually measures the displacement of a test mass using a position measuring circuit. For further digital processing, the measured signal is converted into digital information using an AD converter, for example. As the acceleration of the test mass is directly proportional to the force acting on the body, the acceleration can be measured indirectly via a force acting on one of the axes of the acceleration sensor. Acceleration sensors preferably comprise bores, cavities, springs and channels, which are produced using micromachining processes known in the prior art. The acceleration forces can be measured based on the displacement of the test mass in relation to fixed electrodes.

A common measurement method used in acceleration sensors is capacitive in nature. The acceleration is detected as a change in the capacitance of the moving test mass. Typical features of this technology are its high accuracy and stability, low power loss and simple structure. Its susceptibility to noise and temperature fluctuations is low. The displacement of the moving mass caused by acceleration, which is in the micrometer range, results in an extremely small change in the capacitance which is to be detected. This requires the use of a large number of moving masses and fixed electrodes connected in parallel. This arrangement results in a higher change in capacitance, which can be detected more precisely and makes the capacitive technique more practicable overall. The reduction of parasitic capacitances according to the invention can therefore entail in particular better measurement results for such methods.

Gyroscopes (also known simply as gyros for short) are components that measure or maintain rotational movements. They are compact, low-cost sensors that measure angular velocity. The units of angular velocity are measured in degrees per second (°/s) or revolutions per second (RPS). Gyroscopes can be used to determine orientation and can be found in most autonomous navigation systems. During a rotation, a small test mass is displaced when the angular velocity changes. This movement is converted into very weak electrical signals that can be amplified and read by a microcontroller, for example. The functional principle of many well-known gyroscopes is capacitive in nature, as described in the section above on acceleration sensors.

Pressure sensors comprise capacitors mounted on a wafer or a microchip, for example, which can be formed via the sensor structure. When pressure is applied, the distances between the sensor structures and thus also the capacitances are changed. This functional principle is also capacitive. However, pressure sensors can also be based on other physical principles. For example, inductive pressure sensors, piezoresistive pressure sensors or pressure sensors based on the Hall effect.

A MEMS microphone preferably refers to a microphone whose structures for generating or picking up sound at least partially exhibit dimensions in the micrometer range (1 μm to 1000 μm). Preferably, a vibratable diaphragm can exhibit dimensions in the range of less than 1000 μm in width, height and/or thickness.

The vibratable diaphragm is preferably set up to generate or pick up pressure waves of the fluid. The fluid can be either a gaseous or a liquid fluid, preferably concerning sound pressure waves. A MEMS microphone therefore preferably converts pressure waves (e.g. acoustic signals as alternating sound pressures) into electrical signals. By means of the electronic circuit, the vibrations of the vibratable membrane can preferably be read out by piezoelectric, piezoresistive and/or capacitive components and/or effects.

Flow sensors are used to detect the flow rate of fluid flows. Flow sensors can be based on thermal and non-thermal principles. The most common non-thermal flow sensors in the prior art are the so-called drag force sensors, pressure drop sensors and Coriolis sensors.

The thermal principle is based on the convective heat transfer of an electrically heated resistor into the passing fluid, which leads to cooling of the heater as a function of the flow rate and can therefore be detected electrically. As the convective heat transfer is directly proportional to the mass flow, these sensors are mass flow sensors. There are basically three different types of flow sensors, namely hot-wire or hot-film sensors (thermal anemometers), calorimetric sensors and time-of-flight sensors.

A gas sensor is responsible for detecting gaseous substances. The proportion of certain chemical substances in the gas is converted by the sensor into an electrical signal, for example by the electronic circuit.

A high-frequency component is preferably a component that transmits, receives, blocks and/or lets through electrical and/or electromagnetic signals with frequencies in the high-frequency range. In the prior art, the term “high frequency” is actually not uniformly defined. Frequencies as low as approx. 1 kHz (kilohertz) can be considered, but also frequencies in the MHz (megahertz), GHz (gigahertz) and/or THz (terahertz) range. Digital filters, analog filters, amplifiers, antennas, bias networks, directional couplers, absorber elements, waveguides and/or distribution networks can be used as high-frequency components.

Readout circuits preferably comprise circuit measures that condition the semiconductor component and/or the MEMS device, e.g. in the compensation of certain currents or in noise suppression. Readout circuits can also condition electrical signals in certain ways, for example by logarithmization, amplification or impedance conversion. All these measures help to read out an electrical signal in a suitable form and make it available to a subsequent circuit. In a simple case, the subsequent circuit can be a driver circuit for outputting the signal at a chip output.

An amplifier shapes an input signal in such a way that the time characteristic of this input signal is reproduced, but with higher power. An amplifier therefore generates a “stronger image” of a weak input signal by substantially working as an electrically controllable resistor: When the input signal is low, it presents a high resistance to the voltage from the energy source, so that it is attenuated relatively strongly; when the input signal is higher, it presents a lower resistance, so that the energy can flow relatively unhindered.

So-called switching amplifiers, which can be installed in the semiconductor component according to the invention, also represent a more specialized class of amplifiers. Switching amplifiers can switch a usually considerably larger current (or voltage) on and off with low power. This is often also associated with potential isolation, e.g. when mains voltages are switched.

The provision of a via with extremely low parasitic capacitances according to the invention has an advantageous effect on the various aforementioned semiconductor components.

In a further preferred embodiment, the method is characterized in that the semiconductor component is connected to a MEMS device and/or an electronic circuit by means of die attach technology, flip chip technology, through-hole mounting, surface mounting, bonding technology, laser welding, heat sealing technology, joining processes, adhesive bonding and/or soldering.

The aforementioned connection and assembly techniques have proven to be particularly reliable, robust and simple in the prior art. In particular, electronic and non-electronic (micro) components can be linked together particularly well.

In a further aspect, the invention relates to a semiconductor component produced according to the method according to the invention.

The average person skilled in the art will recognize that technical features, definitions and advantages of preferred embodiments which apply to the method according to the invention for producing a via for a semiconductor component apply equally to the semiconductor component with a via which can be produced according to the invention, and vice versa.

The semiconductor component has a via region that transports current between different vertical conductive path levels. Vertical trenches surround the via region, which provide insulation for the via region. Preferably, the vertical trenches are partially filled with a dielectric and/or the walls and base of the vertical trenches are coated with a dielectric. This has proven to be particularly advantageous, as any parasitic capacitance that occurs is significantly reduced.

In addition, the via region is hermetically sealed by vertical trenches and the vertical trenches are preferably filled with the dielectric in such a way that they are also hermetically sealed themselves. This results in particularly good protection of the via region and the vertical trenches from the environment of the semiconductor component or other sections of the semiconductor component itself. In addition, the via region is configured in such a way that the internal resistance is advantageously minimized. One of the reasons for this is that the via region also advantageously exhibits a small lateral extension. The small lateral extension of the via region is realized, for example, by the vertical trenches comprising an opening and a widened region and the widened region being laterally widened so that the via region is laterally restricted.

Furthermore, due to the small dimensions of the via region, it can be connected particularly well and particularly easily to cavities within a wafer or a wafer stack in which a MEMS device and/or an electronic circuit is preferably present.

The method according to the invention will be explained in more detail below using examples, without being limited to these examples.

### FIGURES

### Brief Description of the Illustrations

FIG. 1 A-Q Illustration of preferred method steps according to a first embodiment of the invention

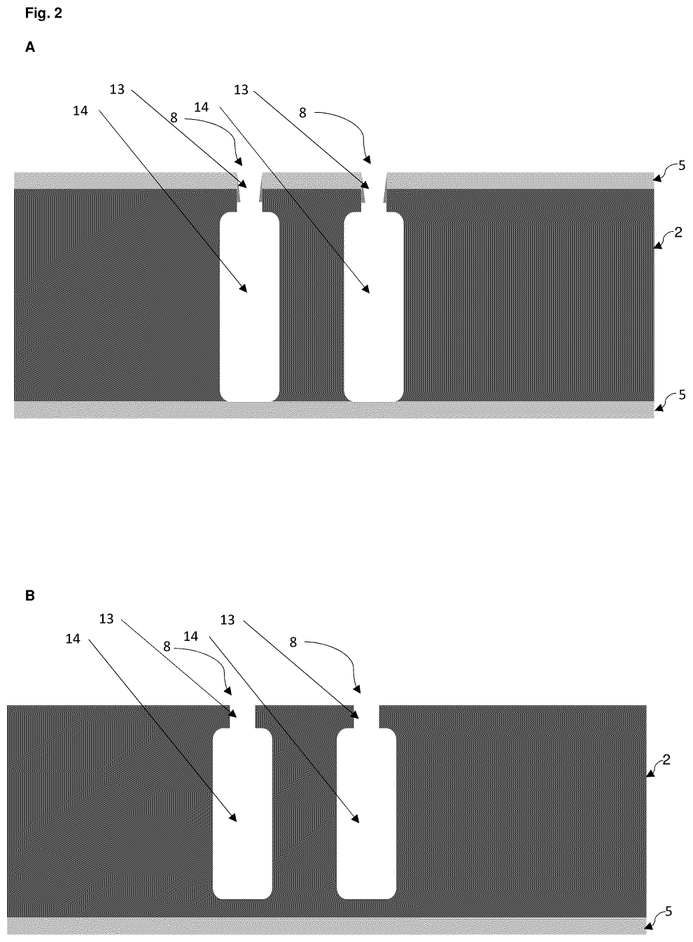

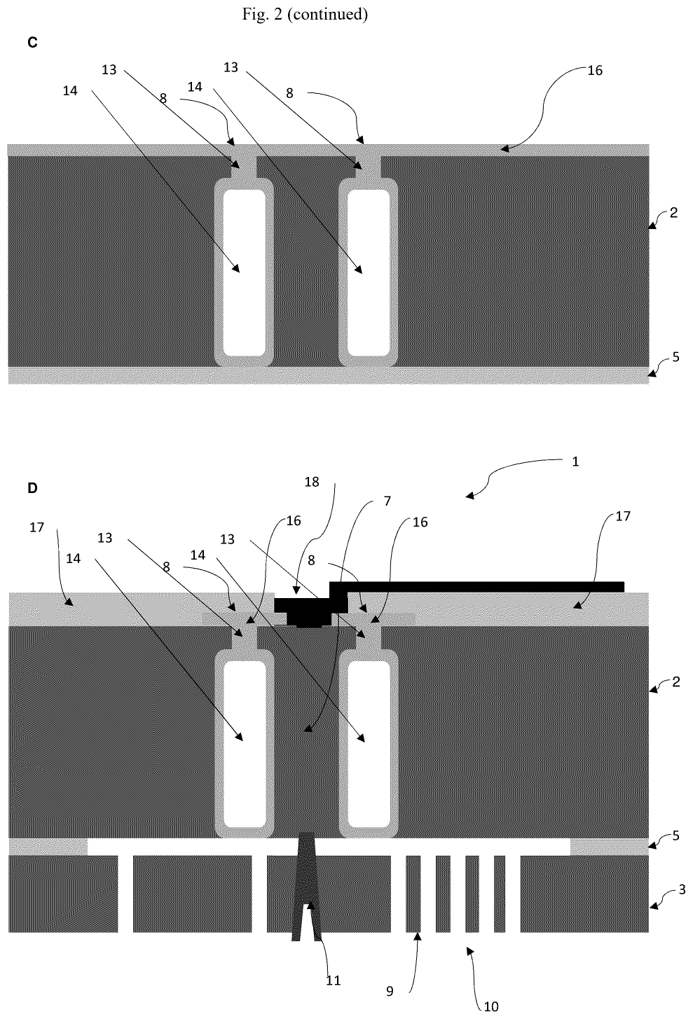

FIG. 2 A-D Illustration of preferred method steps according to a second embodiment of the invention

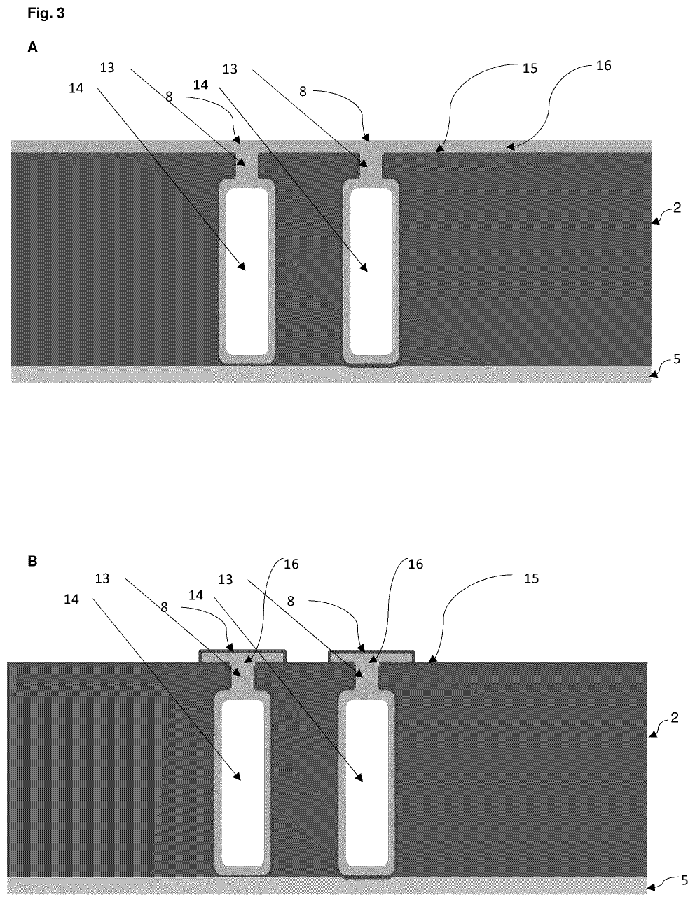

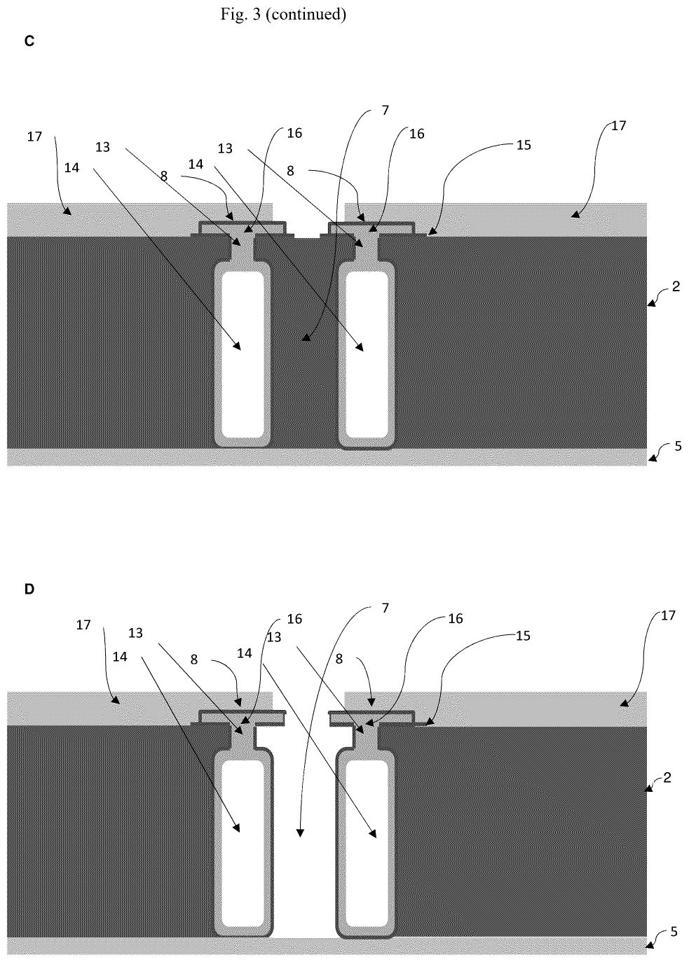

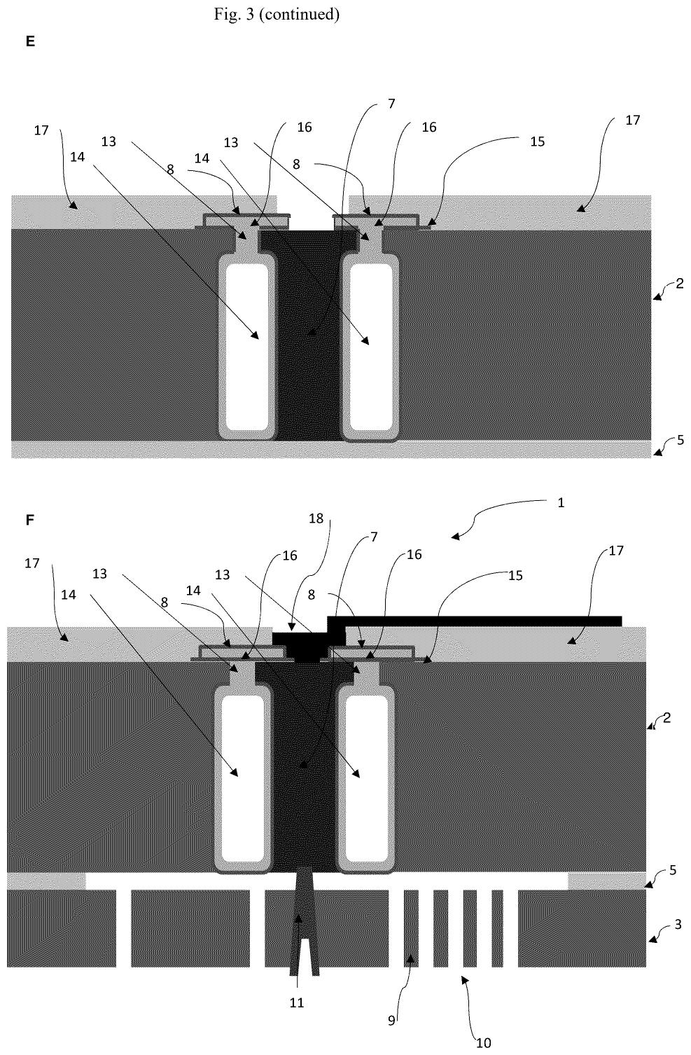

FIG. 3 A-F Illustration of preferred method steps according to a third embodiment of the invention

### DETAILED DESCRIPTION OF THE ILLUSTRATIONS

FIG. 1 shows an illustration of preferred method steps A-Q of a first embodiment of the method according to the invention. As explained above, a semiconductor component 1 is produced with a via region 7, which has proven to be particularly advantageous in particular due to minimal parasitic capacitances and the simultaneous hermetic sealing of the via region 7.

To produce the semiconductor component 1, a first wafer 2 is first provided in method step A.

In method step B, an oxide layer 5 is applied to a front side and a rear side of the first wafer 2 in order to process the first wafer 2 in specific regions and to protect other regions from etching processes accordingly. In particular, the front side represents a contact side of the semiconductor component. The oxide layer 5 is referred to as “oxide hard mask” in method step B.

In method step C, vertical trenches 8 are introduced into the first wafer 2 using an etching process. In this step, the vertical trenches 8 may initially have a width of approximately 5 μm and a depth of approximately 10 μm, for example.

In method step D, side walls of the vertical trenches or part of the side walls of the vertical trenches 8 are coated with a line layer. The line layer may, for example, comprise an oxide and/or TEOS. This line layer also serves to protect the wafer from further etching processes that take place in the subsequent method steps.

In method step E, the vertical trenches 8 are formed by means of further etching processes. Preferably, the vertical trenches 8 extend to the oxide layer on the rear side of the first wafer 2.

In method step F, the vertical trenches 8 are processed with further etching processes, such as wet chemical etching or dry etching, so that they have an opening 13 and a widened region 14. The widened region 14 is formed by a lateral extension of the vertical trenches 8. The formation of the widened region 14 is advantageous because, on the one hand, the via region 7 is reduced laterally and, on the other hand, the distance between the via region 7 and, for example, other via regions, which are not shown, is increased in order to reduce parasitic capacities. In addition, the ratio of area and distance according to equation (1) is constituted with this method step in such a way that the internal resistance of the via region is advantageously reduced.

In method step G, the oxide layer 5 on the front side of the first wafer 2 is optionally removed. The line layer is also removed in this method step.

In method step H, the first wafer 2, in particular the vertical trenches 8, is provided with a sealing layer 15. The sealing layer 15 advantageously protects the vertical trenches 8 and/or the first wafer 2 from under-vapor etching processes, which take place in the subsequent steps. In addition, the sealing layer 15 in combination with a dielectric 16 results in a particularly good hermetic sealing of the via region 7 and the vertical trenches 8. The sealing layer 15 can, for example, be silicon nitride and/or silicon oxynitride.

In method step I, the vertical trenches 8 are filled with the dielectric 16, whereby it is preferred that the first wafer 2 is coated with the dielectric 16 over its entire surface. The dielectric 16 can be TEOS and/or silicon dioxide, for example. Preferably, the dielectric 16 is additionally structured, which is not shown, in order to obtain the dielectric 16 over the opening 13 of the vertical trenches and to remove it from further surfaces of the first wafer 2. The vertical trenches 8 are only partially filled with the dielectric. This can be achieved by coating the side walls and the bottom of the vertical trenches 8 with the dielectric.

In method step J, the sealing layer 15 is coated again to ensure a particularly good hermetic seal of the vertical trenches 8. It may comprise the same or a different material. Also not shown, but preferred, the sealing layer 15 is structured so that it is only present over the opening 13 and forms a connection region for the via region 7.

In method step K, the first wafer 2 is coated with an insulating layer 17, wherein the connection region of the via region 7 is not provided with the insulating layer 17. The insulating layer 17 enables targeted electrical contact between a connection pad 18 and the via region 7 and prevents undesired contact with other regions of the first wafer 2, so that short circuits, for example, are avoided.

In method step L, the connection pad 18, for example a metal, is connected to the via region 7.

In method step M, a second wafer 3 is bonded to the rear side of the first wafer 2. In particular, an SOI wafer (characterized by the label “SOI for MEMS”) is formed. SOI wafers have the advantage that they are less sensitive to interference radiation (e.g. ionizing radiation) and mutual interference with the active components. In addition, the semiconductor component 1 with an SOI wafer exhibits a lower capacitance and can be switched faster. Lower power losses are also achieved.

In method step N, a connection opening 11 is formed from the second wafer 3 to the via region 7 of the semiconductor component 1.

In method step O, the connection opening 11 is filled with a conductive material so that an electrical connection is formed and both connection regions of the via region 7 are electrically connected in order to enable a closed circuit and thus operation.

In method step P, sensor structures 9 for a MEMS device 10 are formed using etching processes starting from the second wafer 3. The sensor structures 9 are formed up to the oxide layer 5 so as not to damage the first wafer 2.

In method step Q, an under-vapor etching process is used to remove the oxide layer 5 over the sensor structures 9 and thus make them freely vibratable, so that various MEMS devices 10 can be realized as described above.

FIG. 2 shows an illustration of preferred method steps A-D of a further embodiment of the method according to the invention. The embodiment according to FIG. 2 dispenses with a sealing layer 15; instead, the vertical trenches 8 are “directly” partially filled with the dielectric 16, for example by thermal oxidation of silicon.

In method step A, the first wafer 2 is provided with the oxide layer 5 on its front and rear sides. The vertical trenches 8 comprise the opening 13 and the widened region 14. The method steps carried out for this purpose are not shown here. Optionally, in method step B, the oxide layer 5 on the front side of the first wafer 2 and the line layer at the opening 13 of the vertical trenches 8 are removed. In method step C, the vertical trenches 8 are partially filled with the dielectric 16, preferably by coating the first wafer 2 in a planar manner and coating the side walls with the dielectric 16. In particular, the vertical trenches 8 are sealed in a planar manner with the dielectric 16. The partial filling of the vertical trenches 8 results in significantly lower parasitic capacitances and the planar sealing of the vertical trenches results in a particularly good hermetic sealing of the vertical trenches 8 and the via region 7, which is particularly advantageous.

The finished semiconductor component 1 is shown in method step D. The electrical connection is formed by filling the connection opening 11 with a conductive material. The electrical connection is also connected to the via region 7 in order to enable operation of the MEMS device 10 and/or the electronic circuit within a cavity of the semiconductor component. The sensor structures 9 are configured to vibrate freely by removing the oxide layer 5 by means of under-vapor etching.

FIG. 3 shows an illustration of preferred method steps A-F of a further embodiment of the invention. In the embodiment according to FIG. 3, the material of the via region 7 is removed and filled with a metal, for example copper, aluminum, iron, zinc, tin, tungsten, gold, their compounds and/or alloys.

Method step A shows the first wafer 2, the vertical trenches 8 of which have already been partially filled with the sealing layer 15 and the dielectric 16.

In method step B, the dielectric 16 is structured and the first wafer 2 is coated with a further sealing layer 15 so that the vertical trenches 8 are particularly well hermetically sealed.

In method step C, the front side of the first wafer 1 is coated with the insulating layer 17 in order to enable targeted electrical connection of the via region 7 with a connection pad 18.

In method step D, the wafer material of the via region 7 is removed using an etching process.

In method step E, the via region is filled with a metal. This embodiment is advantageous in that the vias 7 have a considerably lower internal resistance.

The finished semiconductor component 1 is shown in method step F. The electrical connection is established by filling the connection opening 11 with a conductive material. The connection pad 18 is also connected to the via region 7 in order to enable operation of the MEMS device 10 and/or the electronic circuit within a cavity. The sensor structures 9 are made freely vibratable by removing the oxide layer 5 using an under-vapor etching process.

### REFERENCE LIST

1 Semiconductor component
2 First wafer
3 Second wafer
5 Oxide layer
7 Via region
8 Vertical trenches
9 Sensor structure(s)
10 MEMS device
11 Connection opening
13 Opening
14 Widened region
15 Sealing layer
16 Dielectric
17 Insulating layer
18 Connection pad

### BIBLIOGRAPHY

Zhang, Lan, et al. “Amorphous fluoropolymer protective coatings for front-side MEMS releasing by hydrofluoric acid vapor etching.” Microelectronic engineering 117 (2014) 18-25

1. A method for producing a via for a semiconductor component comprising at least one wafer, comprising the following steps:
(a) forming vertical trenches within the wafer, which enclose a via region,
(b) coating and sealing the vertical trenches with a dielectric, the vertical trenches being only partially filled with the dielectric, and
(c) connection of the via region to an electrical connection.

2. The method according to claim 1, wherein the semiconductor component comprises a MEMS device and/or an electronic circuit which are operated by connecting the via region to the electrical connection.

3. The method according to claim 1, wherein the via region (7) extends partially and/or continuously through the wafer.

4. The method according to claim 1, wherein the wafer exhibits a front and rear side, wherein the via extends from the front side to the rear side, a MEMS device and/or an electronic circuit is/are present on the rear side, which is/are connected to the via region.

5. The method according to claim 4, wherein the semiconductor component exhibits a cavity in which a MEMS device and/or an electronic circuit is present, wherein the cavity is present within a wafer stack formed by at least two wafers and the via region extends through at least one of the two wafers, wherein a negative pressure is present within the cavity.

6. The method according to claim 1, wherein the vertical trenches are filled with a porous low-k dielectric.

7. The method according to claim 1, wherein a negative pressure is present within the vertical trenches after sealing and/or these are filled with a gas before sealing.

8. The method according to claim 1, wherein the vertical trenches exhibit an opening and, starting from a width of the opening, are widened laterally to form a widened region, wherein preferably the vertical trenches in the area of a widened region are additionally widened laterally by at least 2 μm, compared to the width of an opening, wherein the lateral widening is less than 20 μm, and/or the opening exhibits a depth of less than 5 μm and a width of less than 2 μm and/or the widened region exhibits a width of at least 10 μm.

9. The method according to claim 1, wherein the vertical trenches are formed by wet chemical etching processes and/or dry etching processes and/or the vertical trenches exhibit an aspect ratio of up to 50:1 and/or a depth of between 100 μm and 1000 μm.

10. The method according to claim 1, wherein the vertical trenches are sealed with a dielectric and/or the vertical trenches are hermetically sealed by coating with the dielectric and/or a sealing layer is additionally applied for hermetic sealing, wherein the dielectric for partially filling and coating the vertical trenches and/or the sealing layer comprises silicon nitride, tetraethyl orthosilicate, silicon oxynitride and/or silicon dioxide.

11. The method according to claim 1 for providing a connection of an electrical connection for operating the MEMS device and/or the electronic circuit to the via region, a region of the via region is connected to a conductive material or a connection opening is formed in a wafer of a wafer stack, which is filled with a conductive material.

12. The method according to claim 1, wherein a connection pad is applied to a contact side of the wafer or wafer stack on the via region, an insulating layer, at least partially omitting the via region, and the connection pad being formed by filling the omitted region with a conductive material.

13. The method according to claim 1, wherein the via region between the vertical trenches is removed and filled with a metal.

14. The method according to claim 1, wherein the semiconductor component exhibits a MEMS device and/or an electronic circuit, wherein the MEMS device comprises an acceleration sensor, a gyroscope, a pressure sensor, a microphone, a flow sensor and/or a gas sensor and/or the electronic circuit comprises a high-frequency component, an integrated readout circuit and/or an amplifier.

15. A semiconductor component with a via produced according to a method according to claim 1.

16. The method of claim 5, wherein the negative pressure is a vacuum.

17. The method of claim 6, wherein the porous low-k dielectric is selected from the group consisting of porous organic materials, porous carbon-doped silicon oxide, silica gel, silicate aerogels, mesoporous silicon nitride, polysilicon and/or TEOS (tetraethyl orthosilicate), porous hydrogen silsesquioxane, mesoporous silicate glasses, phosphorus particles and aluminum oxide particles.

18. The method of claim 7, wherein the vertical trenches are filled with a gas that exhibits a lower dielectric constant than the dielectric for sealing.

19. The method of claim 9 wherein the vertical trenches are formed by physical and/or chemical dry etching processes.

20. The method of claim 19, wherein the vertical trenches are formed by reactive ion etching and/or reactive ion deep etching (Bosch process).
